(19) United States
(12) Patent Application Publication
(10) Pub. No.: US 2024/0220443 A1
(43) Pub. Date: Jul. 4, 2024

(54) APPARATUS AND METHOD FOR CONTROLLING PROCESS-IN-MEMORY BY ACCELERATING CONVOLUTION OPERATION BASED ON ARRANGING PATTERN OF WEIGHT IN KERNEL, AND STORAGE MEDIUM STORING INSTRUCTIONS TO PERFORM METHOD FOR CONTROLLING PROCESS-IN-MEMORY

(71) Applicant: Research & Business Foundation SUNGKYUNKWAN UNIVERSITY, Suwon-si (KR)

(72) Inventors: Jong Hwan KO, Suwon-si (KR); Johnny RHE, Suwon-si (KR)

(73) Assignee: Research & Business Foundation SUNGKYUNKWAN UNIVERSITY, Suwon-si (KR)

(21) Appl. No.: 18/398,389

(22) Filed: Dec. 28, 2023

(30) Foreign Application Priority Data
Dec. 28, 2022 (KR) 10-2022-0187676

(51) Int. Cl. G06F 15/78; G11C 7/10

(52) U.S. Cl. CPC G06F 15/7821; G11C 7/1006

(57) ABSTRACT

There is provided a processing-in-memory (PIM) control device. The device comprises a memory configured to store one or more instructions; and a processor configured to execute the one or more instructions stored in the memory, wherein the instructions, when executed by the processor, cause the processor to determine input data, weights, and information on a size of a kernel, which is a unit for performing convolution operations using the input data and the weights, determine a pattern for arranging each weight in the kernel, arrange first weights corresponding to the determined pattern in the kernel to map each first weight to a plurality of memory cells included in a PIM array, and control the PIM array to perform the convolution operations using first input data corresponding to the size of the kernel and the first weights.

### TECHNICAL FIELD

The present disclosure relates to a PIM control device, method, computer-readable recording medium, and computer program that accelerates a convolution operation based on a weight array pattern of a kernel.

This work was partly supported by National Research Foundation of Korea grant funded by the Korea government(MSIT: Ministry of Science and ICT) (Research for mutual optimization simulation framework for efficient in-memory deep learning operations (No. 2022R1F1A1074142), and Industry-academia collaborative IoT semiconductor system convergence manpower development center support project (No. 2020M3H2A1076786)), and Institute for Information & communications Technology Promotion(IITP) grant funded by the Korea government(MSIT) (Artificial intelligence graduate school support project (No. 2019-0-00421), ICT luxury talent development support project (No. 2020-0-01821), Research and development of artificial intelligence innovation hub (No. 2021-0-02068), Core technology development and manpower training support project for artificial intelligence system semiconductor for smart mobility (No. 2021-0-02052), and Spatial precision optimal control research for efficient and robust in-memory deep learning inference (No. 00251438)).

### BACKGROUND ART

A Processing-In-Memory (PIM) has been attracting attention as an appropriate means for a Convolutional Neural Network (CNN) inference due to energy-efficient structure of the PIM.

When performing the convolution operation of the CNN through the PIM, in order to reduce unnecessary operations and improve operation speed, a technique which omits operations on PIM array rows with a weight of 0 by using weight sparsity of the CNN is called row-skipping. (J.-H. Kim, J. Lee, J. Lee, J. Heo, and J.-Y. Kim, “Z-pim: A sparsity-aware processing-in-memory architecture with fully variable weight bit-precision for energy-efficient deep neural networks,” IEEE Journal of Solid-State Circuits, vol. 56, no. 4, pp. 1093-1104, 2021.)

Meanwhile, since each row of a memory cell that makes up a PIM array is connected to all columns, when performing row skipping, in a case where there is even one non-zero value in a specific row of the PIM array, the operation for that row cannot be omitted.

In particular, since weight values of 0 are irregularly mixed during the convolution operation of the CNN, when performing the convolution operation on the PIM array, the probability that specific rows of the PIM array will all have 0 values is low, and thus, it is not possible to provide a high row-skipping ratio. In addition, as a channel size of the weight mapped to the PIM array increases, more rows of memory cells are used, and thus, the probability of performing row skipping becomes lower.

### DETAILED DESCRIPTION OF INVENTION

An object of the present disclosure is to propose a technology that maximizes a row skipping ratio during convolution operation in a PIM array by determining a weight arrangement pattern of a kernel in consideration of a structure of the PIM array and weight sparsity of the CNN.

The aspects of the present disclosure are not limited to the foregoing, and other aspects not mentioned herein will be clearly understood by those skilled in the art from the following description.

In accordance with an aspect of the present disclosure, there is provided a processing-in-memory (PIM) control device, the device comprises: a transceiver that obtains information on a first terminal and a second terminal: and a memory configured to store one or more instructions: and a processor configured to execute the one or more instructions stored in the memory, wherein the instructions, when executed by the processor, cause the processor to: determine input data, weights, and information on a size of a kernel, which is a unit for performing convolution operations using the input data and the weights, determine a pattern for arranging each weight in the kernel, arrange first weights corresponding to the determined pattern in the kernel to map each first weight to a plurality of memory cells included in a PIM array, and control the PIM array to perform the convolution operations using first input data corresponding to the size of the kernel and the first weights.

Additionally, the processor may be configured to determine the pattern to cause computing operations equal to a preset number of entries within the kernel when the weights for performing the convolution operations are arranged in the kernel based on the preset number of entries which is a number of the computing operations using the input data and the weights within the kernel.

Additionally, the processor may be configured to arrange the first weights equal to the preset number of entries of the kernel in each entry of the kernel corresponding to the determined pattern, and arrange 0 or null in residual entry of the kernel.

Additionally, kernel may have three-dimensional entries having a predetermined width size, a predetermined height size, and a predetermined depth size, the PIM array may include the plurality of memory cells arranged a predetermined row size, and a predetermined column size, and the processor may be configured to map the first weights arranged within the kernel to each memory cell included in each column of the PIM array.

Additionally, the processor may be configured to arrange each entry of the kernel with arranged the first weights in at least one column of the PIM array, and map each first weight arranged in each entry of the kernel to each memory cell included in the at least one column of the PIM array.

Additionally, the processor may be configured to determine the pattern arranged to the first weights to be same with each pattern arranged to the three-dimensional entries located at the predetermined width and the predetermined height on a same depth in a plurality of kernels.

Additionally, the PIM array may include the plurality of the memory cells arranged a predetermined row size, and a predetermined column size, and the processor may be configured to control the PIM array to input each first input data into the respective memory cells located at the row of the PIM array and perform the convolution operations for computing the first input data and first weights included in the memory cells located at the column of the PIM array, and to skip the convolution operations for computing the first input data input and weights mapped to the respective memory cells located at a first row of the PIM array when all weights of the memory cells located at the first row of the PIM array have 0 or null.

In accordance with another aspect of the present disclosure, there is provided a PIM control method, the method comprises: determining input data, weights, and information on a size of a kernel, which is a unit for performing convolution operations using the input data and the weights; determining a pattern for arranging each weight in the kernel: arranging first weights corresponding to the determined pattern in the kernel to map each first weight to a plurality of memory cells of included in a PIM array; and controlling the PIM array to perform the convolution operations using first input data corresponding to the size of the kernel and the first weights.

Additionally, the determining the pattern may include determining the pattern to cause computing operations equal to a preset number of entries within the kernel when the weights for performing the convolution operations are arranged in the kernel based on the preset number of entries which is a number of the computing operations using the input data and the weights within the kernel.

Additionally, the arranging first weights may include arranging the first weights equal to the preset number of entries of the kernel in each entry of the kernel corresponding to the determined pattern and arranges 0 or null in residual entry of the kernel.

Additionally, the kernel may have three-dimensional entries having a predetermined width size, a predetermined height size, and a predetermined depth size, the PIM array may include the plurality of memory cells arranged a predetermined row size, and a predetermined column size, and the arranging first weights may include mapping the first weights arranged within the kernel to each memory cell included in each column of the PIM array.

Additionally, the mapping the first weights may include arranging each entry of the kernel with arranged the first weights in at least one column of the PIM array and mapping each first weight arranged in each entry of the kernel to each memory cell included in the at least one column of the PIM array.

Additionally, the determining the pattern may include determining the pattern arranged to the first weights to be same with each pattern arranged to the three-dimensional entries located at the predetermined width and the predetermined height on a same depth in a plurality of kernels.

Additionally, the PIM array may include the plurality of the memory cells arranged a predetermined row size, and a predetermined column size, and the controlling the PIM array may include controlling the PIM array to input each first input data into the respective memory cells located at the row of the PIM array, to perform the convolution operations for computing the first input data and first weights included in the memory cells located at the column of the PIM array, and to skip the convolution operations for computing the first input data input and weights mapped to the respective memory cells located at a first row of the PIM array when all weights of the memory cells located at the first row of the PIM array have 0 or null.

In accordance with another aspect of the present disclosure, there is provided a non-transitory computer readable storage medium storing computer executable instructions, wherein the instructions, when executed by a processor, cause the processor to perform a PIM control method, the terminal control method comprise: determining input data, weights, and a size of a kernel, which is a unit for performing convolution operations using the input data and the weights; determining a pattern for arranging each weight in the kernel: arranging first weights corresponding to the determined pattern in the kernel to map each first weight to a plurality of memory cells of included in a PIM array: and controlling the PIM array to perform the convolution operations using first input data corresponding to the size of the kernel and the first weights.

In accordance with another aspect of the present disclosure, there is provided a computer program including computer executable instructions stored in a non-transitory computer readable storage medium, wherein the instructions, when executed by a processor, cause the processor to perform a PIM control method, the terminal control method comprise: determining input data, weights, and a size of a kernel, which is a unit for performing convolution operations using the input data and the weights: determining a pattern for arranging each weight in the kernel; arranging first weights corresponding to the determined pattern in the kernel to map each first weight to a plurality of memory cells of included in a PIM array: and controlling the PIM array to perform the convolution operations using first input data corresponding to the size of the kernel and the first weights.

According to one embodiment of the present disclosure, the weight arrangement pattern of the kernel is determined in consideration of the structure of the PIM array and the characteristics of weight sparsity to maximize the row skipping ratio, and thus, it is possible to improve a computation speed and reduce energy consumption during convolution operation in the PIM array.

The effects that can be obtained from the present disclosure are not limited to the effects mentioned above, and other effects not mentioned can be clearly understood by those skilled in the art from the description below.

### BRIEF DESCRIPTION OF THE DRAWING

FIG. 1 is a functional block diagram of a PIM control device that accelerates a convolution operation based on a weight array pattern of a kernel according to one embodiment.

FIG. 2 is an exemplary diagram for explaining an operation of performing a convolution operation on a PIM array according to one embodiment.

FIG. 3 is an exemplary diagram for explaining an operation of determining a pattern for arranging a weight in the kernel according to one embodiment.

FIG. 4 is an exemplary diagram illustrating an operation for determining a pattern to arrange weights in the kernel based on a preset number of entries, which is the number of times an operation between input data and the weight is performed within the kernel, according to one embodiment.

FIG. 5 illustrates a parallel window (PW) configured using a Shift and duplicate kernel (SDK) according to one embodiment.

FIGS. 6A to 6E are exemplary diagrams illustrating a pattern set using SDK mapping according to one embodiment.

FIG. 7 is a flowchart of a PIM control method performed by a PIM control device according to one embodiment.

### BEST MODE FOR CARRYING OUT THE INVENTION

The advantages and features of the embodiments and the methods of accomplishing the embodiments will be clearly understood from the following description taken in conjunction with the accompanying drawings. However, embodiments are not limited to those embodiments described, as embodiments may be implemented in various forms. It should be noted that the present embodiments are provided to make a full disclosure and also to allow those skilled in the art to know the full range of the embodiments. Therefore, the embodiments are to be defined only by the scope of the appended claims.

Terms used in the present specification will be briefly described, and the present disclosure will be described in detail.

In terms used in the present disclosure, general terms currently as widely used as possible while considering functions in the present disclosure are used. However, the terms may vary according to the intention or precedent of a technician working in the field, the emergence of new technologies, and the like. In addition, in certain cases, there are terms arbitrarily selected by the applicant, and in this case, the meaning of the terms will be described in detail in the description of the corresponding invention. Therefore, the terms used in the present disclosure should be defined based on the meaning of the terms and the overall contents of the present disclosure, not just the name of the terms.

When it is described that a part in the overall specification “includes” a certain component, this means that other components may be further included instead of excluding other components unless specifically stated to the contrary.

In addition, a term such as a “unit” or a “portion” used in the specification means a software component or a hardware component such as FPGA or ASIC, and the “unit” or the “portion” performs a certain role. However, the “unit” or the “portion” is not limited to software or hardware. The “portion” or the “unit” may be configured to be in an addressable storage medium, or may be configured to reproduce one or more processors. Thus, as an example, the “unit” or the “portion” includes components (such as software components, object-oriented software components, class components, and task components), processes, functions, properties, procedures, subroutines, segments of program code, drivers, firmware, microcode, circuits, data, database, data structures, tables, arrays, and variables. The functions provided in the components and “unit” may be combined into a smaller number of components and “units” or may be further divided into additional components and “units”.

Hereinafter, the embodiment of the present disclosure will be described in detail with reference to the accompanying drawings so that those of ordinary skill in the art may easily implement the present disclosure. In the drawings, portions not related to the description are omitted in order to clearly describe the present disclosure.

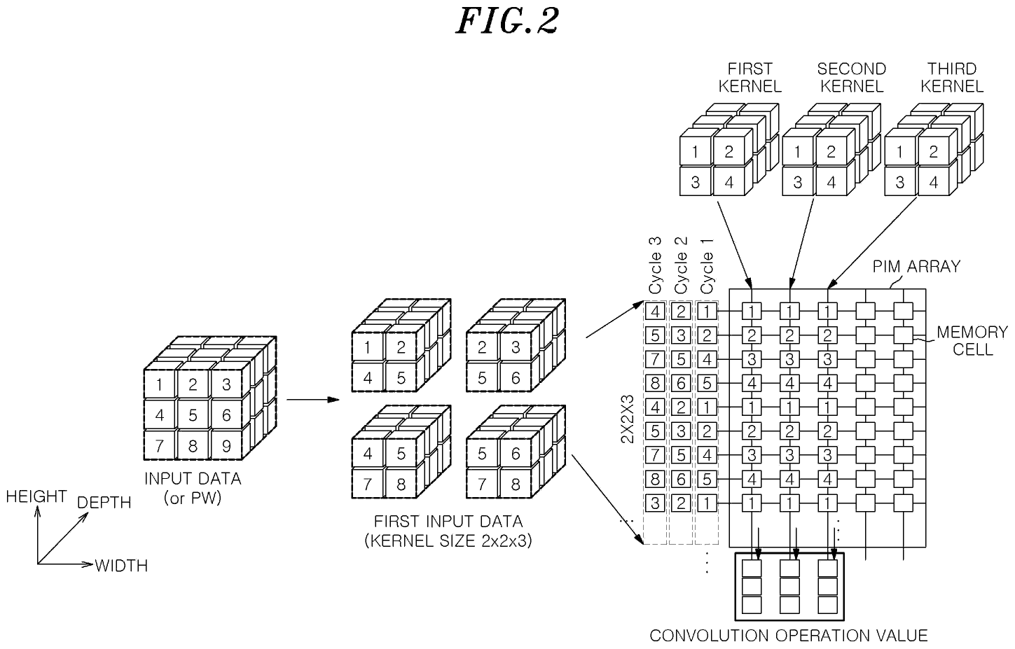

A PIM (Processing-In-Memory) array is a semiconductor that can perform operations within memory. The PIM array may include a memory cell arranged according to a row and a column, a word-line for operating the memory cell, and a bit-line for reading values stored in the memory cells. In this case, when a specific row of the memory cell is turned on, multiplication may be performed between the data input in a row direction of the memory cell and the data stored in the memory cell, and the PIM array may use this principle to perform a convolution operation within the memory. More detailed operations in the PIM array will be described later in FIG. 2.

In the embodiment of this document, when performing a convolution operation using the PIM array, weights are arranged in each column of the memory cell based on a pattern of a kernel. Accordingly, the embodiment of this document provides a technology to increase a ratio of row-skipping, which omits the operation of a PIM array row when the values stored in the memory cells of a specific row all have the value 0.

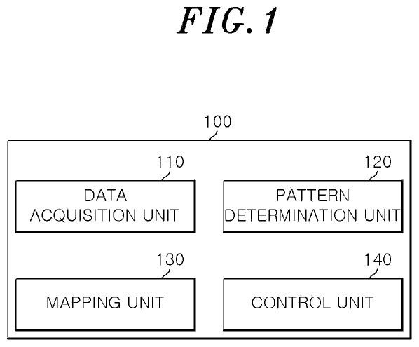

Hereinafter, embodiments of the present document will be described with reference to FIGS. 1 to 5.

FIG. 1 is a functional block diagram of a PIM control device 100 (hereinafter, referred to as a “PIM control device 100”) that accelerates a convolution operation based on a weight array pattern of a kernel according to one embodiment.

Referring to FIG. 1, the PIM control device 100 according to one embodiment may include a data acquisition unit 110, a pattern determination unit 120, a mapping unit 130, and a control unit 140. The overall operation of each module included in the PIM control device 100 according to one embodiment may be performed by one or more processors, and the one or more processors may perform control so that modules included in FIG. 1 perform operations to be described later.

Although, in one embodiment of the present disclosure, the PIM control device 100 according to one embodiment includes modules such as the data acquisition unit 110, the pattern determination unit 120, the mapping unit 130, and the control unit 140. However, the present disclosure is not limited thereto, and it is sufficient to be able to perform the operations described later. For example, the PIM control device 100 may be configured to include a memory (not illustrated) that stores instructions for executing a PIM control program and one or more processors that execute instructions stored in the memory. Additionally, the PIM control program may include a program in which the modules included in FIG. 1 perform operations be described later.

The data acquisition unit 110 may acquire data necessary to perform a convolution operation. For example, data required to perform a convolution operation may include input data on which to perform the convolution operation, and a weight applied to perform the convolution operation. In addition, since convolution in computer operations is performed in kernel units, the data acquisition unit 110 may obtain information about the size of the kernel, which is a unit for performing the convolution operation between input data and the weight in the PIM array, and the size of the PIM array.

The data acquired by the data acquisition unit 110 may be used in the convolution operation of the PIM array as illustrated in the example of FIG. 2 below.

FIG. 2 is an exemplary diagram for explaining an operation of performing a convolution operation on a PIM array according to one embodiment. FIG. 2 illustrates that the input data (or Parallel Window in the Shifted and duplicated kernel technique) is 3D data with a size of 3×3×3 (width×height×depth), the kernel size is 2×2×3 (width×height×depth), and the convolution operation in the PIM array is performed by using three types of kernels (first kernel, second kernel, and third kernel). Hereinafter, one embodiment of determining the pattern in which weights are arranged in the kernel will be described based on the example in FIG. 2. Meanwhile, examples of the size of the input data, the number of kernels, the size of the kernel, the size of the PIM array, or the like in FIG. 2 are only examples for convenience of understanding, and the embodiments of this document are not limited to these examples.

Referring to FIG. 2, the input data may be cut by the kernel size, which is the unit in which the convolution operation is performed. When 3×3×3 input data is cut into the kernel size of 2×2×3, four first input data corresponding to the size of 2×2×3 may be generated. Each of the first input data may be input to each row of the PIM array for each operation cycle. The first kernel, second kernel, and third kernel may include weights to perform the convolution operation as much as the kernel size of 2×2×3, and the weight of each kernel may be mapped to each column of the PIM array. Accordingly, the PIM array in FIG. 2 may perform the convolution operation according to the weights of the three kernels per cycle by performing multiplication between the first input data input in the row direction of the memory cell and the weights of the three kernels stored in the memory cell.

The pattern determination unit 120 may determine the pattern to arrange the weight in the kernel.

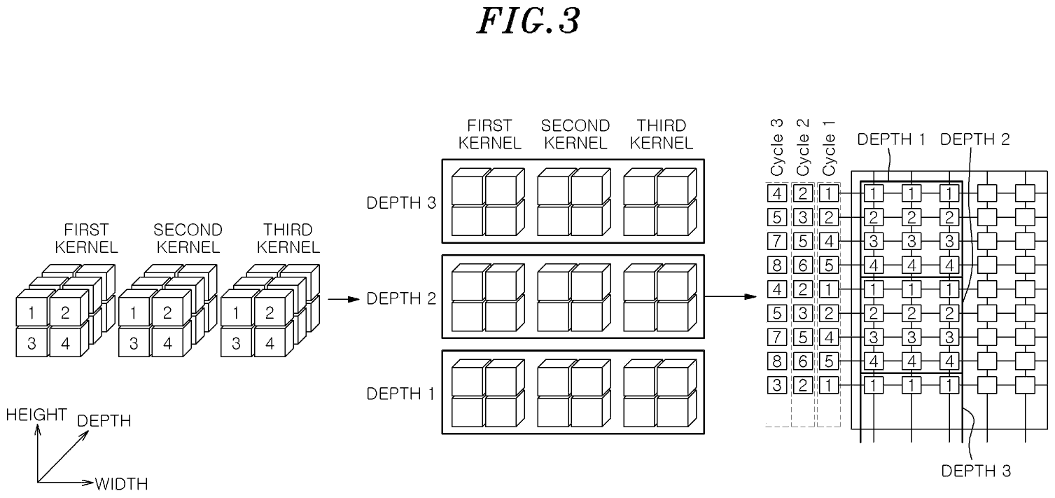

FIG. 3 is an exemplary diagram for explaining an operation of determining the pattern for arranging the weight in the kernel according to one embodiment.

Referring to FIG. 3, the pattern determination unit 120 may perform determination so that all the patterns of the first weight located at the same depth (for example, depth 1, depth 2, depth 3) in each of a plurality of kernels (for example, first kernel, second kernel, third kernel) and arranged in a two-dimensional kernel having width×height have the same pattern. In other words, by arranging weights in the kernel positions corresponding to a specific pattern and arranging 0 or null in the remaining positions of the kernel, when the weights arranged in each kernel are mapped to the PIM array, all specific rows of the PIM array may have values of 0 or null.

As an example, the pattern determination unit 120 may determine a pattern to arrange weights in the kernel based on a preset number of entries, which is the number of times an operation between input data and weights is performed within the kernel.

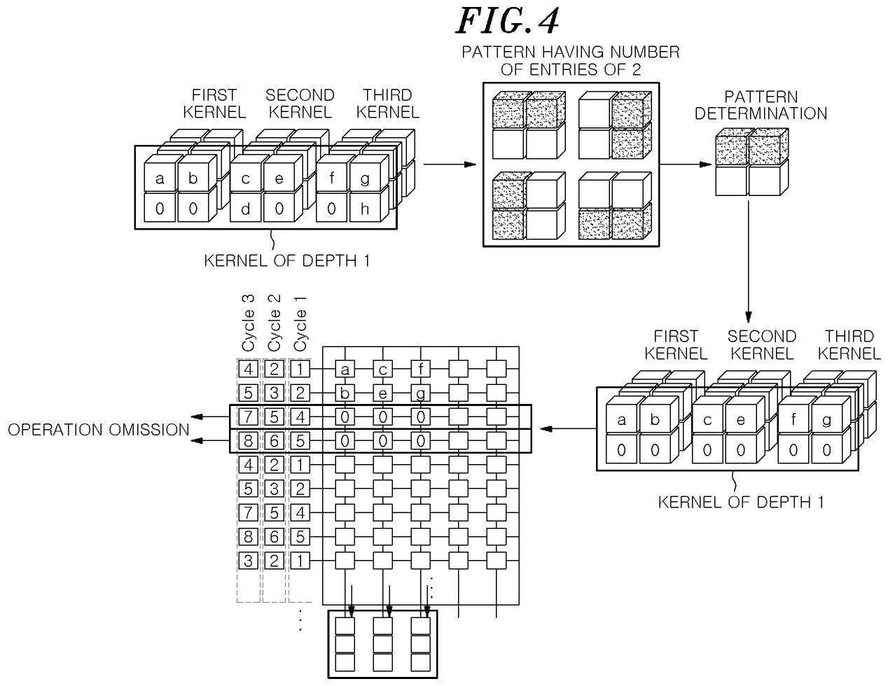

FIG. 4 is an example of an operation for determining the pattern to arrange the weights in the kernel based on the preset number of entries, which is the number of times an operation between input data and weights is performed within the kernel, according to one embodiment. FIG. 4 is an example assuming that the number of weight entries arranged in each kernel of width×height size located at the same “depth 1” is “2”. The pattern determination unit 120 may determine different numbers of entries and patterns to be applied to the two-dimensional kernels of depth 1, depth 2, and depth 3. Since the principle of determining the pattern applied to the two-dimensional kernel of depth 2 and depth 3 is the same as “depth 1”, the explanation of FIG. 4 to be described later will be based on “depth 1”.

Referring to FIG. 4, when arranging weights in the kernel for the convolution operation, different weights may be arranged in the first to third kernels of depth 1. In this case, when the number of entries, which is the number of times an operation is performed in each kernel corresponding to “depth 1”, is set to “2”, in the pattern of arranging the weights so that two operations are performed in a 2×2 sized 2-dimensional kernel of “depth 1”, as described in the example of FIG. 4, there may be four cases. The pattern determination unit 120 may determine the pattern that can contain the most weight in the first to third kernels of “depth 1” among all patterns according to the number of cases.

The mapping unit 130 may arrange the first weight in the first to third kernels in the positions corresponding to the determined pattern, and arrange 0 or null values in the remaining positions. The mapping unit 130 may map the first weights arranged in the first to third kernels to each row of the memory cells of the PIM array.

The control unit 140 may control the PIM array to perform the convolution operation between the first input data and the first weight corresponding to the size of the kernel. As the PIM array of FIG. 4, when all values included in the memory cell of a specific row are 0 or null, the control unit 140 may perform control so that the convolution operation between the first input data input to the row and the value mapped to the memory cell of the first row is omitted.

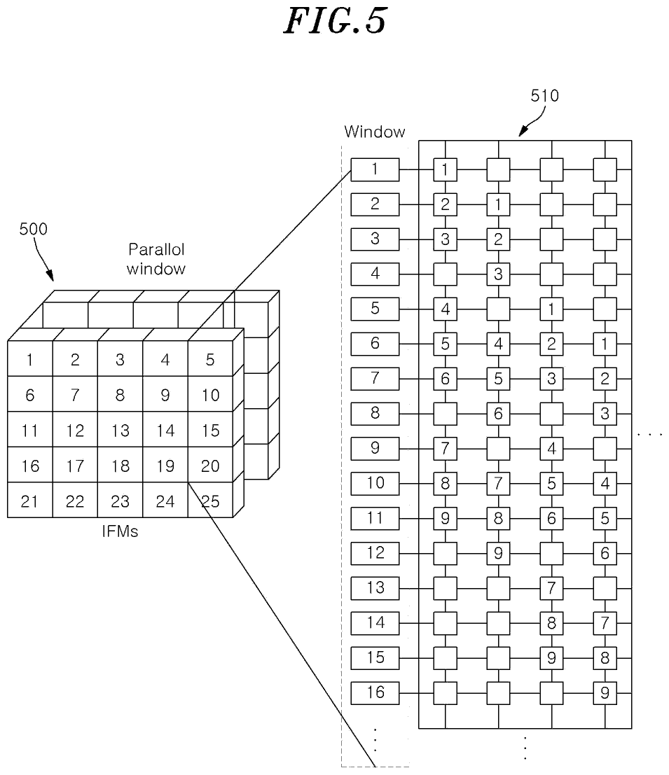

FIG. 5 illustrates a parallel window (PW) configured using a shift and duplicate kernel (SDK) according to one embodiment.

Referring to FIG. 5, a PW 510 may be configured so that the weight of the kernel is copied based on an SDK method for an input feature map 500, the position is rearranged, and the input data is reused by mapping to an unused column. The configuration of the PW 510 may be performed by the pattern determination unit 120. The pattern decision unit 120 may determine the parallel size by checking how many times the same kernel can be mapped, and configure the PW 510 according to the determined parallel size.

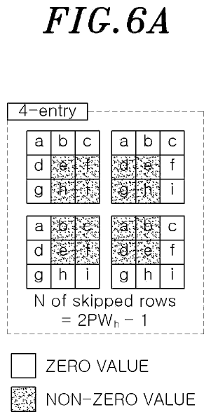

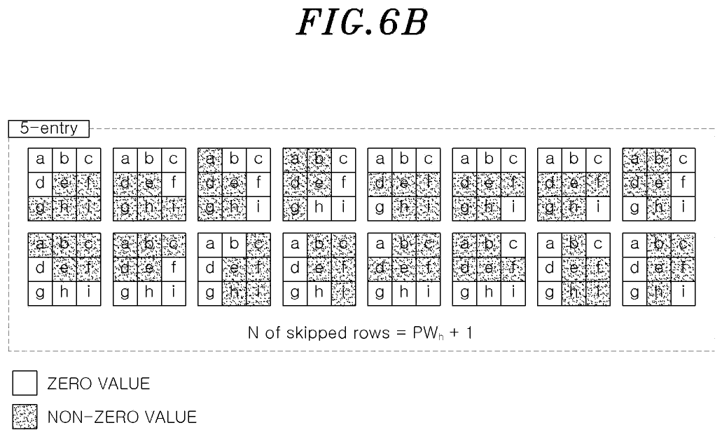

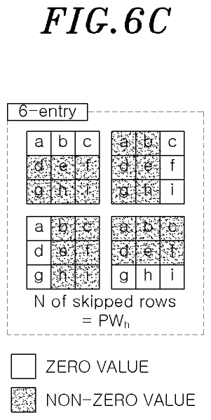

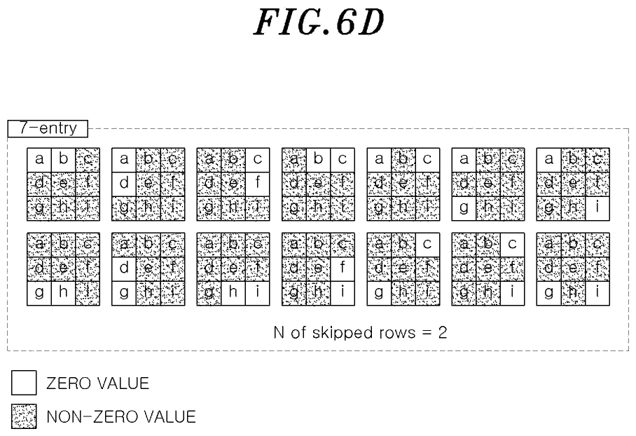

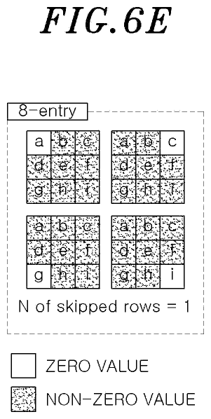

FIGS. 6A to 6E are exemplary diagrams illustrating a pattern set using the SDK mapping according to one embodiment.

Specifically, FIG. 6A illustrates pattern sets that may be row-skipped when there are four entries, FIG. 6B illustrates pattern sets that may be row-skipped when there are five entries, FIG. 6C illustrates pattern sets that may be row-skipped when there are six entries, FIG. 6D illustrates pattern sets that may be row-skipped when there are seven entries, and FIG. 6E illustrates pattern sets that may be row-skipped when there are eight entries.

When configuring PW using the SDK, weight elements at different positions in the same kernel may be mapped to the same row in order to reuse input data that is used redundantly caused by the stride of the kernel. Even when a specific weight element is 0, a row may not be skipped due to another weight element. Therefore, when the SDK mapping method is used, the number of rows to be skipped varies depending on which pattern is used, and a pattern that can skip the most rows must be found to reduce the computing cycle. To this end, the pattern determination unit 120 may check how many entries exist in the row and determine a pattern set among pattern sets determined according to the number of confirmed entries. For example, the pattern determination unit 120 may check the importance by performing the operation of Equation 1 below on pattern sets determined according to the number of entries, and select the pattern set with the highest importance value as the optimal pattern.

$$\\ \begin{matrix}{I}^{{}_{} IC} = {\sum }_{n = 1}^{OC} \text{?} \vert {W}_{( n , m )}^{{}_{} IC} , {M}_{( n , m )}^{{}_{} IC} \vert , & [ Equation 1 ]\end{matrix}$$

$$\\ \text{?} \text{indicates text missing or illegible when filed}$$

Here, IIC is the importance, W is the weight, M is a mask to make the weight 0, IC is an input channel, OC is an output channel, and k is the kernel.

Additionally, the mapping unit 130 may map the weight of the identified pattern, and the control unit 140 may control the PIM array to perform the convolution operation between the input data corresponding to the size of the kernel and the weight of the determined pattern.

By configuring the PW using the SDK and setting the weight according to the pattern determined based on the configuration, more columns are used than the conventional method, and thus, there is a high probability that a non-zero weight is mapped to the column, and the skip-row ratio can be lowered.

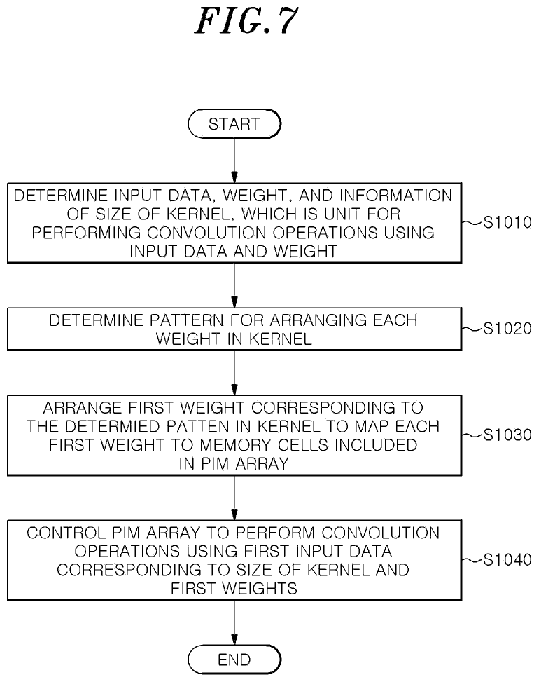

FIG. 7 is a flowchart of a PIM control method performed by the PIM control device 100 according to one embodiment. Each step of the determination method according to FIG. 5 may be performed by the PIM control device 100 illustrated in FIG. 1, and each step is described as follows.

In Step S1010, the data acquisition unit 110 acquires information about the input data, the weight, and the size of the kernel, which is a unit for performing the convolution operation between the input data and the weight.

In Step S1020, the pattern determination unit 120 may determine the pattern to arrange the weight in the kernel.

In Step S1030, the mapping unit 130 may arrange the first weight in the kernel in a form corresponding to the determined pattern and map the first weight to the memory cell of the PIM array.

In Step S1040, the control unit 140 may control the PIM array to perform the convolution operation between the first input data corresponding to the size of the kernel and the first weight. Meanwhile, in addition to the steps illustrated in FIG. 5, the embodiments in which the above-described data acquisition unit 110, pattern determination unit 120, mapping unit 130, and control unit 140 perform the operations described with FIGS. 1 to 4 may be configured in various ways, new steps performed by each module may be added to the step in FIG. 5, the configuration of additional steps and the operations of the components responsible for each step to perform the steps have been described in FIGS. 1 to 4, and thus, duplicate descriptions will be omitted.

According to the above-described embodiment, the weight arrangement pattern of the kernel is determined in consideration of the structure of the PIM array and the weight sparsity of the CNN to maximize the row skipping ratio, and thus, it is possible to improve the computation speed improved and reduce energy consumption during the convolution operation in the PIM array.

Combinations of steps in each flowchart attached to the present disclosure may be executed by computer program instructions. Since the computer program instructions can be mounted on a processor of a general-purpose computer, a special purpose computer, or other programmable data processing equipment, the instructions executed by the processor of the computer or other programmable data processing equipment create a means for performing the functions described in each step of the flowchart. The computer program instructions can also be stored on a computer-usable or computer-readable storage medium which can be directed to a computer or other programmable data processing equipment to implement a function in a specific manner. Accordingly, the instructions stored on the computer-usable or computer-readable recording medium can also produce an article of manufacture containing an instruction means which performs the functions described in each step of the flowchart. The computer program instructions can also be mounted on a computer or other programmable data processing equipment. Accordingly, a series of operational steps are performed on a computer or other programmable data processing equipment to create a computer-executable process, and it is also possible for instructions to perform a computer or other programmable data processing equipment to provide steps for performing the functions described in each step of the flowchart.

In addition, each step may represent a module, a segment, or a portion of codes which contains one or more executable instructions for executing the specified logical function(s). It should also be noted that in some alternative embodiments, the functions mentioned in the steps may occur out of order. For example, two steps illustrated in succession may in fact be performed substantially simultaneously, or the steps may sometimes be performed in a reverse order depending on the corresponding function.

The above description is merely exemplary description of the technical scope of the present disclosure, and it will be understood by those skilled in the art that various changes and modifications can be made without departing from original characteristics of the present disclosure. Therefore, the embodiments disclosed in the present disclosure are intended to explain, not to limit, the technical scope of the present disclosure, and the technical scope of the present disclosure is not limited by the embodiments. The protection scope of the present disclosure should be interpreted based on the following claims and it should be appreciated that all technical scopes included within a range equivalent thereto are included in the protection scope of the present disclosure.

What is claimed is:

1. A processing-in-memory (PIM) control device comprising:
a memory configured to store one or more instructions; and
a processor configured to execute the one or more instructions stored in the memory, wherein the instructions, when executed by the processor, cause the processor to:
determine input data, weights, and information on a size of a kernel, which is a unit for performing convolution operations using the input data and the weights,
determine a pattern for arranging each weight in the kernel,
arrange first weights corresponding to the determined pattern in the kernel to map each first weight to a plurality of memory cells included in a PIM array, and
control the PIM array to perform the convolution operations using first input data corresponding to the size of the kernel and the first weights.

2. The PMI control device of claim 1, wherein the processor is configured to determine the pattern to cause computing operations equal to a preset number of entries within the kernel when the weights for performing the convolution operations are arranged in the kernel based on the preset number of entries which is a number of the computing operations using the input data and the weights within the kernel.

3. The PMI control device of claim 2, wherein the processor is configured to arrange the first weights equal to the preset number of entries of the kernel in each entry of the kernel corresponding to the determined pattern, and arrange 0 or null in residual entry of the kernel.

4. The PMI control device of claim 1, wherein the kernel has three-dimensional entries having a predetermined width size, a predetermined height size, and a predetermined depth size,
wherein the PIM array includes the plurality of memory cells arranged a predetermined row size, and a predetermined column size, and
wherein the processor is configured to map the first weights arranged within the kernel to each memory cell included in each column of the PIM array.

5. The PMI control device of claim 4, wherein the processor is configured to arrange each entry of the kernel with arranged the first weights in at least one column of the PIM array, and map each first weight arranged in each entry of the kernel to each memory cell included in the at least one column of the PIM array.

6. The PMI control device of claim 5, wherein the processor is configured to determine the pattern arranged to the first weights to be same with each pattern arranged to the three-dimensional entries located at the predetermined width and the predetermined height on a same depth in a plurality of kernels.

7. The PMI control device of claim 1, wherein the PIM array includes the plurality of the memory cells arranged a predetermined row size, and a predetermined column size, and
wherein the processor is configured to control the PIM array to input each first input data into the respective memory cells located at the row of the PIM array and perform the convolution operations for computing the first input data and first weights included in the memory cells located at the column of the PIM array, and to skip the convolution operations for computing the first input data input and weights mapped to the respective memory cells located at a first row of the PIM array when all weights of the memory cells located at the first row of the PIM array have 0 or null.

8. A PIM control method executed by a PIM control device, the method comprising:
determining input data, weights, and information on a size of a kernel, which is a unit for performing convolution operations using the input data and the weights:
determining a pattern for arranging each weight in the kernel:
arranging first weights corresponding to the determined pattern in the kernel to map each first weight to a plurality of memory cells of included in a PIM array; and controlling the PIM array to perform the convolution operations using first input data corresponding to the size of the kernel and the first weights.

9. The method of claim 8, wherein the determining the pattern includes determining the pattern to cause computing operations equal to a preset number of entries within the kernel when the weights for performing the convolution operations are arranged in the kernel based on the preset number of entries which is a number of the computing operations using the input data and the weights within the kernel.

10. The method of claim 9, wherein the arranging first weights includes arranging the first weights equal to the preset number of entries of the kernel in each entry of the kernel corresponding to the determined pattern and arranges 0 or null in residual entry of the kernel.

11. The method of claim 8, wherein the kernel has three-dimensional entries having a predetermined width size, a predetermined height size, and a predetermined depth size, wherein the PIM array includes the plurality of memory cells arranged a predetermined row size, and a predetermined column size, and
wherein the arranging first weights includes mapping the first weights arranged within the kernel to each memory cell included in each column of the PIM array.

12. The method of claim 11, wherein the mapping the first weights includes arranging each entry of the kernel with arranged the first weights in at least one column of the PIM array and mapping each first weight arranged in each entry of the kernel to each memory cell included in the at least one column of the PIM array.

13. The method of claim 12, wherein the determining the pattern includes determining the pattern arranged to the first weights to be same with each pattern arranged to the three-dimensional entries located at the predetermined width and the predetermined height on a same depth in a plurality of kernels.

14. The method of claim 8, wherein the PIM array includes the plurality of the memory cells arranged a predetermined row size, and a predetermined column size, and
wherein the controlling the PIM array includes controlling the PIM array to input each first input data into the respective memory cells located at the row of the PIM array, to perform the convolution operations for computing the first input data and first weights included in the memory cells located at the column of the PIM array, and to skip the convolution operations for computing the first input data input and weights mapped to the respective memory cells located at a first row of the PIM array when all weights of the memory cells located at the first row of the PIM array have 0 or null.

15. A non-transitory computer readable storage medium storing computer executable instructions, wherein the instructions, when executed by a processor, cause the processor to perform a PIM control method, the method comprising:
determining input data, weights, and a size of a kernel, which is a unit for performing convolution operations using the input data and the weights:
determining a pattern for arranging each weight in the kernel:
arranging first weights corresponding to the determined pattern in the kernel to map each first weight to a plurality of memory cells of included in a PIM array; and
controlling the PIM array to perform the convolution operations using first input data corresponding to the size of the kernel and the first weights.

16. The non-transitory computer-readable storage medium of claim 15, wherein the determining the pattern includes determining the pattern to cause computing operations equal to a preset number of entries within the kernel when the weights for performing the convolution operations are arranged in the kernel based on the preset number of entries which is a number of the computing operations using the input data and the weights within the kernel.

17. The non-transitory computer-readable storage medium of claim 16, wherein the arranging first weights includes arranging the first weights equal to the preset number of entries of the kernel in each entry of the kernel corresponding to the determined pattern and arranges 0 or null in residual entry of the kernel.

18. The non-transitory computer-readable storage medium of claim 17, wherein the kernel has three-dimensional entries having a predetermined width size, a predetermined height size, and a predetermined depth size,
wherein the PIM array includes the plurality of memory cells arranged a predetermined row size, and a predetermined column size, and
wherein the arranging first weights includes mapping the first weights arranged within the kernel to each memory cell included in each column of the PIM array.

19. The non-transitory computer-readable storage medium of claim 18, wherein the mapping the first weights includes arranging each entry of the kernel with arranged the first weights in at least one column of the PIM array and mapping each first weight arranged in each entry of the kernel to each memory cell included in the at least one column of the PIM array.

20. The non-transitory computer-readable storage medium of claim 19, wherein the determining the pattern includes determining the pattern arranged to the first weights to be same with each pattern arranged to the three-dimensional entries located at the predetermined width and the predetermined height on a same depth in a plurality of kernels.
